(19) United States
(12) Patent Application Publication
(10) Pub. No.: US 2026/0247900 A1
(43) Pub. Date: Aug. 20, 2026

(54) SENSOR ARRAY, APPARATUS FOR DISPENSING A VAPOR PHASE REACTANT TO A REACTION CHAMBER AND RELATED METHODS

(71) Applicant: ASM IP Holding B.V., Almere (NL)

(72) Inventor: Yoshio Susa, Tokyo (JP)

(21) Appl. No.: 19/646,881

(22) Filed: Apr. 14, 2026

Related U.S. Application Data
(63) Continuation of application No. 17/893,383, filed on Aug. 23, 2022, now Pat. No. 12,628,603.
Application No. 17/893,383 is a division of application No. 16/108,950, filed on Aug. 22, 2018, now Pat. No. 11,430,674.

(51) Int. Cl. H10P 72/00; C23C 16/448; C23C 16/52

(52) U.S. Cl. CPC H10P 72/0421; C23C 16/4481; C23C 16/52; H10P 72/0406

(57) ABSTRACT

An apparatus for dispensing a vapor phase reactant to a reaction chamber is disclosed. The apparatus may include: a vessel having an inner volume configured to contain a liquid chemical; an array of sensors configured for detecting a fill level of the liquid chemical disposed within the inner volume, wherein the array of sensors are vertically distributed within the inner volume with an irregular vertical interval between adjacent sensors. The apparatus may also include: an inlet disposed in the vessel and configured for providing a carrier gas into the inner volume; and an outlet disposed in the vessel and configured for dispensing the vapor phase reactant from the inner volume to the reaction chamber. A sensor array for detecting the fill level of a liquid chemical is also disclosed, as well as methods for dispensing a vapor phase reactant to a reaction chamber.

### CROSS-REFERENCE TO RELATED APPLICATIONS

This application is a continuation of, and claims priority to, U.S. patent application Ser. No. 17/893,383 filed Aug. 23, 2022 titled SENSOR ARRAY, APPARATUS FOR DISPENSING A VAPOR PHASE REACTANT TO A REACTION CHAMBER AND RELATED METHODS; which is a divisional of U.S. patent application Ser. No. 16/108,950 filed Aug. 22, 2018 (now U.S. Pat. No. 11,430,674 issued on Aug. 30, 2022) titled SENSOR ARRAY, APPARATUS FOR DISPENSING A VAPOR PHASE REACTANT TO A REACTION CHAMBER AND RELATED METHODS, the disclosures of which are hereby incorporated by reference in their entirety.

### FIELD OF INVENTION

The present disclosure relates generally to sensor arrays and an apparatus for dispensing a vapor phase reactant to a reaction chamber and in particular to an apparatus including a vessel for containing a liquid chemical, which includes an array of sensors configured for detecting the fill level of the liquid chemical. The disclosure also includes methods for dispensing a vapor phase reactant to a reaction chamber.

### BACKGROUND OF THE DISCLOSURE

Semiconductor processing apparatus commonly use one or more vapor phase reactants, i.e., precursors, as source chemicals for performing semiconductor substrate processes, such as, for example, deposition, cleaning, and etching processes. The vapor phase reactants may be contained in a source vessel in a liquid state and are subsequently converted to a vapor state for transport to a reaction chamber associated with a semiconductor processing apparatus.

High volume semiconductor fabrication facilities may utilize a large volume of liquid chemicals resulting in the requirement to either regularly re-charge the vessel with additional precursor, or alternatively, frequently exchange the discharged vessel for full vessels.

However, there are some forms of liquid chemical precursor which are not readily adaptable for re-charge of the vessel. For example, a particular liquid chemical may be easily degraded or a particular liquid chemical may become strongly attached to the inner surface of the vessel during the re-charge procedure. In addition, the exchange of the discharged vessel for a full vessel may incur undesirable down time for the semiconductor processing apparatus and may also necessitate the need for safe storage of a large number of chemical vessels. Therefore, there is a desire to limit the frequency of chemical vessel exchanges or chemical vessel re-charges.

One fundamental method for reducing the frequency of chemical vessel exchange or chemical vessel re-charge is to increase the size of the vessel thereby allowing the vessel to store more liquid chemical precursor. For example, deposition processes, such as, for example, atomic layer deposition processes, may utilize one or more chemical vessels as the precursor source(s) for the deposition of materials. The chemical vessel may be connected to a source of one or more carrier gases. The carrier gases may be introduced into the chemical vessel and drawn over the surface of, or bubbled through, the liquid chemical contained within the vessel. The resulting evaporation of the liquid chemical causes a vapor of the liquid chemical to become entrained in the carrier gas to thereby produce the vapor phase reactant which can be dispensed to a reaction chamber.

It has been found that the maximum evaporation rate of the liquid chemical occurs directly below the carrier gas inlet, i.e., where the carrier gas flow is most proximate to the liquid chemical. It has also been found that as the liquid chemical is consumed, the fill level of the liquid chemical reduces, increasing the distance between the carrier gas inlet and the exposed surface of the liquid chemical. The increase in distance between the carrier gas inlet and the exposed surface of the liquid chemical can result in an unwanted variation in the vapor phase reactant flow out from the chemical vessel to the reaction chamber. For example, as the liquid chemical within the vessel is consumed and the distance between the carrier gas inlet and the exposed surface of the liquid chemical increases, the flow of vapor phase reactant from the chemical vessel to the reaction chamber may decrease, resulting in an undesirable variation in semiconductor processing conditions.

Accordingly, apparatus and methods are desirable for monitoring the fill level of a liquid chemical disposed within a vessel and regulating a semiconductor process in response to the fill level of the liquid chemical within the vessel.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments of the disclosure, an apparatus for dispensing a vapor phase reactant to a reaction chamber is provided. The apparatus may comprise: a vessel having an inner volume configured to contain a liquid chemical; an array of sensors configured for detecting a fill level of the liquid chemical disposed within the inner volume, wherein the array of sensors are vertically distributed within the inner volume with an irregular vertical interval between adjacent sensors; an inlet disposed in the vessel and configured for providing a carrier gas into the inner volume; and an outlet disposed in the vessel and configured for dispensing the vapor phase reactant from the inner volume to the reaction chamber.

In some embodiments of the disclosure, a sensors array configured for detecting the fill level of a liquid in a vessel is provided. The sensor array may comprise: a vertical supports; and an array of sensors configured for detecting a fill level of the liquid disposed within an inner volume of the vessel; wherein the array of sensors comprises a plurality of sensors which are vertically distributed along the vertical support with an irregular vertical interval between adjacent sensors.

In some embodiments of the disclosure, a method for dispensing a vapor phase reactant to a reaction chamber is provided. The method may comprise: flowing a carrier gas into an inlet of a vessel having an inner volume configured to contain a liquid chemical; sensing a fill level of the liquid chemical by providing an array of sensor configured for detecting a fill level of the liquid chemical disposed within the inner volume, wherein the array of sensors are vertically distributed within the inner volume with an irregular vertical interval between adjacent sensors; and flowing a vapor phase reactant from an outlet of the vessel to a reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 is a graph illustrating the non-linear relationship between material deposition rate in an exemplary atomic layer deposition process and the percentage of liquid chemical remaining in a vessel;

FIG. 2 is a cross-sectional schematic diagram of a vessel including an array of sensors according to the embodiments of the disclosure;

FIG. 3 is a cross-sectional schematic diagram of a vessel including an array of sensors and an additional array of sensors according to the embodiments of the disclosure;

FIG. 4 is a cross-section schematic diagram of a vessel including an array of sensors according to additional embodiments of the disclosure; and

FIG. 5 is simplified schematic diagram of a semiconductor processing apparatus comprising a vessel including an array of sensors according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein the term “fill level” may refer to the vertical location of the upper exposed surface of a liquid chemical disposed within a vessel.

The embodiments of the disclosure may include apparatus and methods for dispensing a vapor phase reactant to a reaction chamber. In particular, the embodiments of the disclosure may include a vessel configured for containing a liquid chemical wherein the vessel includes an array of sensors within the inner volume of the vessel. The array of sensors may be configured to detect the fill level of the liquid chemical within the inner volume and generate a control output dependent on the fill level of the liquid chemical. The fill level dependent control output from the array of sensors may be provided to a controller associated with a semiconductor processing apparatus. The controller may in turn generate an associated control signal based on the fill level of the liquid chemical which is utilized to ensure a uniform reaction rate within a reaction chamber associated with the semiconductor processing apparatus. For example, the control output generated by the controller may be utilized to regulate the temperature of one or more heaters associated with the semiconductor processing apparatus wherein the one or more heaters are configured for controlling the temperature of the liquid chemical within the inner volume. Therefore, as the fill level of the liquid chemical decreases, the temperature of the liquid chemical may be modified to ensure a uniform dose of vapor phase reactant is provided to the reaction chamber, thereby allowing a uniform deposition rate of material being deposited within the reaction chamber.

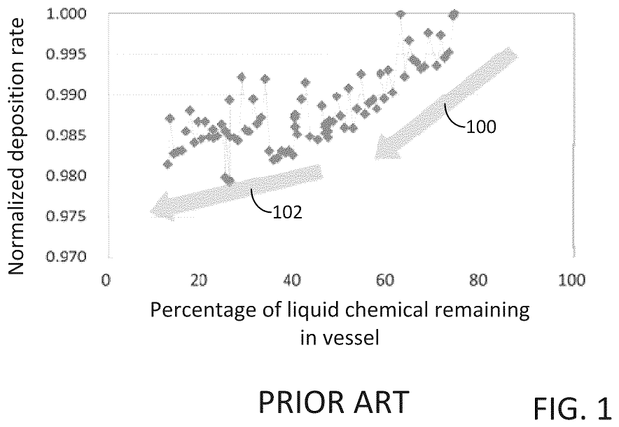

A problem associated with uniformity of deposition rate and the fill level of a liquid chemical in an inner volume of a vessel is illustrated in FIG. 1. FIG. 1 illustrates the relationship between the normalized deposition rate of an exemplary atomic layer deposition process and the percentage of liquid chemical remaining in the vessel. Examination of FIG. 1 indicates that as the volume of liquid chemical in the vessel reduces, i.e., the fill level drops within the vessel, the normalized deposition rate of the exemplary atomic layer deposition process also decreases. Further examination of FIG. 1 illustrates that the decrease observed in the normalized deposition rate is non-linear as indicated by the two distinct regimes labelled as the regime 100 and the regime 102. For example, the normalized deposition rate of the regime 100 and the normalized deposition rate of the regime 102 represent different linear decreases in the normalized deposition rate with the decrease in normalized deposition rate being greater in the regime 100, where the fill level of the liquid chemical is greater, than in the regime 102, where the fill level of the liquid is lower, i.e., the volume of liquid chemical in the inner vessel is most depleted.

Accordingly, it may be advantageous to more closely monitor and control the semiconductor processing apparatus when the fill level of the liquid chemical is greater, as in this regime, i.e., the regime 100, the deposition rate of material is more dependent on a change in fill level within the inner volume of the vessel. Vice versa when the fill level within the inner volume of the vessel is less, i.e., more volume of the liquid chemical has been discharged, less monitoring and control of the semiconductor processing apparatus may be needed, as the deposition rate may be less dependent on the rate of change of the fill level of the liquid chemical within the inner volume of the vessel.

Therefore, the embodiments of the disclosure may include an apparatus for dispensing a vapor phase reactant to reaction chamber. The apparatus may comprise: a vessel having an inner volume configured to contain a liquid chemical; an array of sensor configured for detecting a fill level of the liquid chemical disposed within the inner volume, wherein the array of sensors are vertically distributed within the inner volume with an irregular vertical interval between adjacent sensors. The apparatus may also comprise: an inlet disposed in the vessel and configured for providing a carrier gas into the inner volume; and an outlet disposed in the vessel and configured for dispensing the vapor phase reactant from the inner volume to the reaction chamber.

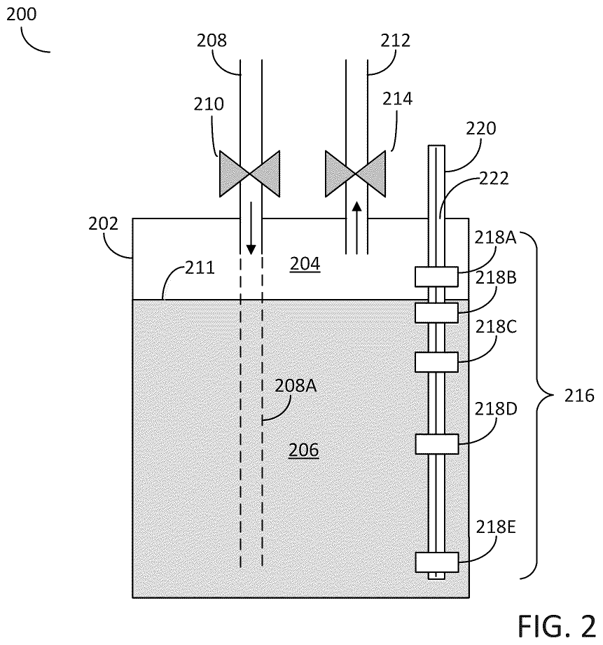

The embodiments of the disclosure may be understood in more detail with reference to FIG. 2 which illustrates a cross-sectional schematic diagram of an exemplary chemical delivery apparatus for dispensing a vapor phase reactant to a reaction chamber according to the embodiments of the disclosure.

In more detail, the apparatus 200 comprises a vessel 202 having an inner volume 204 configured to contain a liquid chemical 206. The vessel 202 may be fabricated from corrosion resistant materials, such as, for example, quartz materials, or stainless steel. The vessel 202 may be configured to contain a liquid chemical 206 up to a maximum volume of the liquid chemical of greater than 2 liters, or greater than 4 liters, or even greater than 6 liters.

The vessel 202 may also comprise an inlet 208 disposed in the vessel 202 and configured for providing a carrier gas into the inner volume 204. In some embodiments, the inlet 208 may provide a carrier gas which enters the inner volume 204 and contacts the liquid chemical 206 at the exposed liquid surface, i.e., the fill level 211. In alternative embodiments, the inlet 208 may extend into the inner volume 204 and further into the liquid chemical 206, as illustrated by dashed line 208A. In such embodiments, the carrier gas injected into the inner volume 204 through the inlet 208, 208A may be bubbled through the liquid chemical 206 to further agitate the liquid chemical 206. The inlet 208 may also comprise a valve 210 utilized to control the flow of the carrier gas into the inner volume 204 of the vessel 202.

The vessel 202 may also comprise an outlet 212 disposed in the vessel 202 and configured for dispensing a vapor phase reactant from the inner volume 204 to a reaction chamber (not shown). The outlet 212 may also comprise a valve 214 utilized to control the flow of the vapor phase reactant from the inner volume 204 of the vessel 202 to a reaction chamber.

The apparatus 200 may also comprise an array of sensors 216 configured for detecting a fill level 211 of the liquid chemical 206 disposed within the inner volume 204, wherein the array of sensors 216 are vertically distributed within the inner volume 204 with an irregular vertical interval between adjacent sensors.

In more detail, the array of sensors 216 may comprise a linear array of sensors including a plurality of individual sensors, such as sensors 218A, 218B, 218C, 218D, and 218E. In some embodiments, each of the sensors may comprise a digital sensor which may either detect the presence of a liquid chemical at the sensor location or alternatively the absence of a liquid chemical at the sensor location. Therefore, the vertically distributed linear array of sensors 216 may sense the fill level of the liquid chemical within the inner volume 204 of the vessel 202. In some embodiment, each of the sensors may comprise a digital ultrasonic sensor.

In some embodiments, the array of sensors 216 may be housed on a vertical support 220 which is disposed in the vessel through vessel port 222. Therefore, in some embodiments, a sensor array configured for detecting the fill level of a liquid within a vessel may comprise: a vertical support 220; and an array of sensors 216 configured for detecting a fill level of the liquid chemical disposed within an inner volume of the vessel, wherein the array of sensors 216 comprises a plurality of sensors (218A, 218B, 218C, 218D, and 218D) which are vertically distributed along the vertical support 220 with an irregular interval between adjacent sensors. In alternative embodiments, the array of sensors may be attached to an internal sidewall of the vessel 202.

In some embodiments of the disclosure, the vertical interval between adjacent sensors may be irregular and in particular embodiments the vertical interval between adjacent sensors may increase from an upper-most sensor 218A to a lower-most sensor 218E, in other words the vertical distance between adjacent sensors may increase from the top of the vessel down to the bottom of the vessel. Therefore, in some embodiments, the concentration of sensors may be greater in an upper portion of the inner volume 204 compared with the concentration of sensors in a lower portion of the inner volume 204.

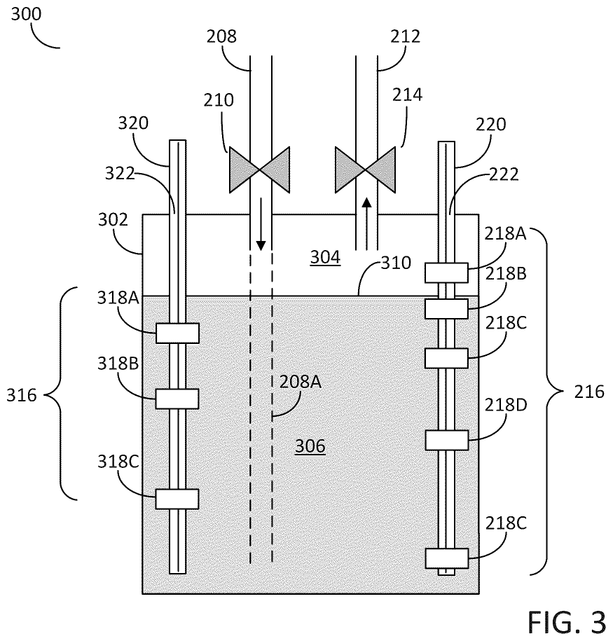

An additional configuration of an apparatus for dispensing a vapor phase reactant to a reaction chamber is illustrated in FIG. 3. The apparatus 300 of FIG. 3 is substantially the same as apparatus 200 of FIG. 2 therefore only the additional elements of apparatus 300 are described in detail.

In more detail, FIG. 3 illustrates a cross-sectional schematic diagram of an apparatus 300 for dispensing a vapor phase reactant to a reaction chamber. The apparatus 300 comprises a vessel 302 configured to contain a liquid chemical 306 and an array of sensors 216 configured for detecting the fill level of the liquid chemical 306 disposed within the inner volume 304, wherein the array of sensors 216 are vertically distributed within the inner volume with an irregular vertical interval between adjacent sensors, as described previously with reference to apparatus 200 of FIG. 2. The vessel 302 also includes an inlet 208 with an associated valve 210 as described previously in reference to apparatus 200 of FIG. 2. The vessel also includes an outlet 212 with an associated valve 214 as also described previously in reference to apparatus 200 of FIG. 2.

The apparatus 300 of FIG. 3 may also comprise an additional array of sensors 316 configured for detecting the fill level 310 of the liquid chemical 306 disposed within the inner volume 304, wherein the additional array of sensors 316 are vertically distributed within the inner volume 304 with an irregular interval between adjacent sensors.

In more detail, the additional array of sensors 316 may comprise a linear array of sensors including a plurality of individual sensors, such as sensors 318A, 318B, and 318C. In some embodiments, each of the sensors of the additional array 316 may comprise a digital sensor which may either detect the presence of a liquid chemical at the sensor location or alternatively the absence of a liquid chemical at the sensor location. Therefore, the vertically distributed linear additional array of sensors 316 may sense the fill level of the liquid chemical 306 within the inner volume 304 of the vessel 302. In some embodiment, each of the sensors of the additional array 316 may comprise a digital ultrasonic sensor.

In some embodiments, the additional array of sensors 316 may be housed on a vertical support 320 which is disposed in the vessel 302 through vessel port 322. In alternative embodiments, the additional array of sensors 316 may be attached to an internal sidewall of the vessel 302. For example, the array sensors 216 and the additional array of sensors 316 may be disposed on opposing sidewalls of the vessel 302.

In some embodiments of the disclosure, the vertical interval between adjacent sensors of the additional array 316 may be irregular and in particular embodiments the vertical interval between adjacent sensors of the additional array 316 may increase from an upper-most sensor 318A to a lower-most sensor 318C, in other words the vertical distance between adjacent sensors may increase from the top of the vessel down to the bottom of the vessel. Therefore, in some embodiments, the concentration of sensors may be greater in an upper portion of the inner volume 304 compared with the concentration of sensors in a lower portion of the inner volume 304.

In some embodiments of the disclosure, each sensor of the array 216 and the additional array 316 may be disposed at a different vertical position within the inner volume 304. For example, as illustrated in FIG. 3 each of the individual sensors of the array 216 (sensors 218A, 218B, 218C, 218D, and 218E) and the additional array 316 (sensors 318A, 318B, and 318C) are disposed at different vertical positions within the inner volume 304 of the vessel 302. The array of sensors 216 and the additional array of sensors 316 may be utilized in combination to detect the fill level 310 of the liquid chemical 306 contained within the vessel 302. The combination of the array 216 and the additional array 316 may enhance the sensitivity of detection of the fill level 310 of the liquid chemical 306 as well as improving detection reliability. For example, when utilizing digital ultrasonic sensors for detecting either the presence or absence of the liquid chemical 306 the sensor signal may be degraded by a number of factors, including, but not limited to, signal noise, heat, or liquid pollutants. Therefore, utilizing a combination of both the array of sensors 216 and the additional array of sensors 316 may minimize the degradation in the detection of the fill level 310 of the liquid chemical 306.

In some embodiments, further linear arrays of sensors may be disposed within the vessel 300 for further improving the sensitivity of the fill level detection and reliability of the detection system. For example, the vessel 302 may include two or more, three or more, or even five or more linear arrays of sensors configured for detecting the fill level 310 within the vessel 302, wherein each individual sensor of the arrays are disposed at different vertical positions within the vessel 302.

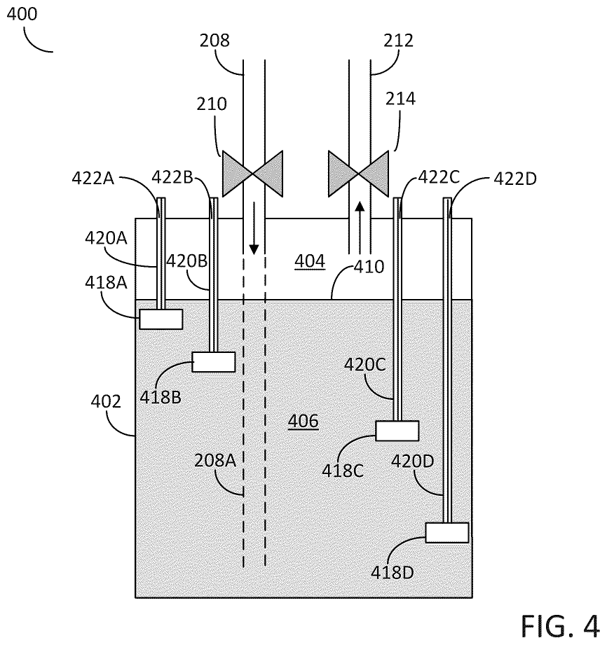

An additional configuration of an apparatus for dispensing a vapor phase reactant to a reaction chamber is illustrated in FIG. 4. The apparatus 400 of FIG. 4 is substantially the same as apparatus 200 of FIG. 2 therefore only the additional elements of apparatus 400 are described in detail.

In more detail, FIG. 4 illustrates a cross-sectional schematic diagram of an apparatus 400 for dispensing a vapor phase reactant to a reaction chamber. The apparatus 400 comprises a vessel 402 configured to contain a liquid chemical 406. The vessel 402 also includes an inlet 208 with an associated valve 210 as described previously in reference to apparatus 200 of FIG. 2. The vessel also includes an outlet 212 with an associated valve 214 as also described previously in reference to apparatus 200 of FIG. 2.

The apparatus 400 may also include an array of sensors configured for detecting the fill level 410 of the liquid chemical 406 disposed within the inner volume 404, wherein the array of sensors are vertically distributed within the inner volume 404 with an irregular vertical interval between adjacent sensors.

In more detail, in this non-limiting example embodiment, each sensor of the array of sensors comprises a vertical support which may be inserted through a vessel port disposed in the lid of the vessel wherein the vertical support is configured for supporting a single sensor at a distinct vertical position within the inner volume 404 of the vessel 402. For example, a first vertical support 420A may be inserted through a first vessel port 422A disposed in the lid of the vessel and the first vertical support 420A may support a first sensor 418A at a first vertical position within the inner volume 404 of the vessel 402. A second vertical support 420B may be inserted through a second vessel port 422B disposed in the lid of the vessel and the second vertical support 420B may support a second sensor 418B at a second vertical position within the inner volume 404. A third vertical support 420C may be inserted through a third vessel port 422C disposed in the lid of the vessel and the third vertical support 420C may support a third sensor 418C at a third vertical position within the inner volume 404. A fourth vertical support 420D may be inserted through a fourth vessel port 422D disposed in the lid of the vessel and the fourth vertical support 420D may support a fourth sensor 418D at a fourth vertical position within the inner volume 404. Any number of vertical supports and their associated sensors may be utilized within the inner volume 404 of the vessel 402. For example, the apparatus 400 may include three (3) or more vertical supports and associated sensors, or five (5) or more vertical supports and associated sensors, or even eight (8) or more vertical supports and associated sensors.

In some embodiments of the disclosure, the vertical interval, i.e., the vertical distance, between adjacent sensors (418A, 418B, 418C, and 418D) may be irregular and in particular embodiments the concentration of sensors in the upper region of the inner volume 404 may be greater than the concentration of sensors in the lower region of the inner volume 404. In some embodiments, each of the sensors (418A, 418B, 418C, and 418D) may comprise a digital sensors which may detect either the presence or absence of the liquid chemical 406 and each of the sensors (418A, 418B, 418C, and 418D) may comprise a digital ultrasonic detector.

The exemplary chemical delivery apparatus and exemplary sensor arrays of the current disclosure may be utilized in a number of applications. As a non-limiting example, the exemplary chemical delivery apparatus and sensors arrays of the current disclosure may be utilized as components of a precursor delivery system configured for supplying one or more precursors to a reaction chamber of a semiconductor processing apparatus.

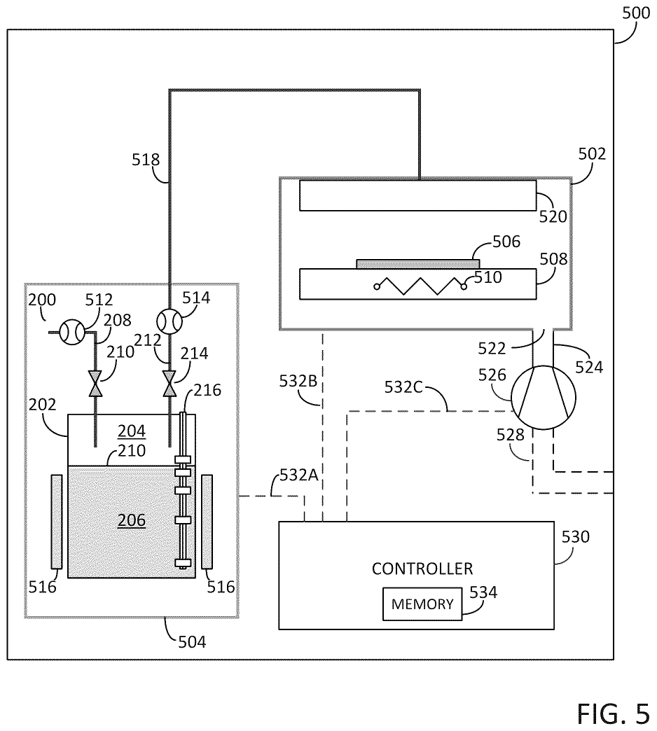

In more detail, FIG. 5 illustrates an exemplary semiconductor processing apparatus 500 which comprises a reaction chamber 502 and a precursor delivery system 504. The precursor delivery system 504 may be configured for supplying vapor phase precursor(s) to the reaction chamber 502 employing the chemical delivery apparatus and sensors arrays of the current disclosure to enable flow control of the precursors to the reaction chamber. It should be noted that the semiconductor processing apparatus 500 is a simplified schematic version of an exemplary semiconductor processing apparatus and does not contain each and every element, i.e., such as each and every valve, gas line, heating element, and reactor component, etc. The semiconductor processing apparatus 500 of FIG. 5 provides the key features of the apparatus to provide sufficient disclosure to one of ordinary skill in the art. For example, the precursor delivery system 504 is illustrated with a single exemplary chemical delivery apparatus 200; however, it should be appreciated that the semiconductor process apparatus 500 and particular the precursor delivery system 504 may employ any number of chemical delivery apparatus to deliver any number of reactants to the reaction chamber 502 associated with the semiconductor processing apparatus 500.

The exemplary semiconductor processing apparatus 500 may comprise a reaction chamber 502 constructed and arranged to hold at least a substrate 506. In some embodiments, the reaction chamber 502 may be configured for one or more of a deposition process, an etching process, or a cleaning process. For example, the reaction chamber 502 may be configured for atomic layer deposition (ALD) processes, or chemical vapor deposition (CVD) processes. The substrate 506 may be disposed in the reaction chamber 502 and held in position by a susceptor 508 configured to retain at least one substrate thereon. The susceptor 508 may comprise a heater 510 configured to heat the substrate to a suitable process temperature.

The precursor delivery system 504 may comprise a chemical delivery apparatus such as the apparatus 200 (FIG. 2), the apparatus 300 (FIG. 3), or the apparatus 400 (FIG. 4). As a non-limiting example, the precursor delivery system 504 is illustrated as utilizing the chemical delivery apparatus 200 of FIG. 2. In abbreviated form, the chemical delivery apparatus 200 may comprise a vessel 202 configured for containing liquid chemical 206. The vessel 202 may include an inlet 208 configured for providing one or more carrier gases into the inner volume 204 of the vessel 202, wherein the inlet 208 comprises a valve 210 to control the flow of carrier and may further comprise a flow controller 512 (e.g., a mass flow controller) for controlling the mass flow of the carrier gas into the vessel 202. The vessel 202 may also include an outlet 212 configured for dispensing a vapor phase reactant to the reaction chamber 502. The outlet 212 may include a valve 214 for controlling the flow of the vapor phase reactant out of the vessel and may further comprise a flow controller 514 (e.g., a mass flow controller) for controlling the mass flow of the vapor phase reactant out of the vessel 202. The vessel 202 may also include an array of sensors 216 configured for detecting the fill level 211 of the liquid chemical 206 disposed in the inner volume 204 of the vessel 200. The array of sensors 216 may be vertically distributed within the inner volume 204 with an irregular vertical interval between adjacent sensors and in particular embodiments the concentration of sensors may be greater in an upper portion of the inner volume 204 compared with the concentration of sensors in a lower portion of the inner volume 204.

The precursor delivery system 504 may also include one or more heaters 516 configured for heating the liquid chemical 206 in the vessel 202 to a desirable temperature set point. The one or more heaters 516 may be disposed adjacent to the vessel 202 and may provide thermal energy through the vessel 202 to the liquid chemical 206 disposed within the inner volume 204 of the vessel 202.

Although not shown in the exemplary precursor delivery system 504 of FIG. 5, the precursor delivery system 504 may include additional chemical delivery apparatus of the current disclosure for dispensing multiple vapor phase reactants to the reaction chamber 502. In addition, the precursor delivery system 504 may include a vessel configured for storing and dispensing a purge gas to the reaction chamber 502.

One or more gas lines, such as exemplary gas line 518, may be in fluid communication with the precursor delivery system 504 to enable the supply of vapor phase reactants and purge gas to the reaction chamber 502. In particular embodiments, the precursor delivery system 504 may be in fluid communication with a gas dispenser 520 configured for dispensing vapor phase reactants and purge gas into the reaction chamber 502 and over the substrate 506. As a non-limiting example, the gas dispenser 520 may comprise a showerhead as illustrated in block form in FIG. 5. It should be noted that the although shown in block form, the showerhead may be a relatively complex structure and may be configured for either mixing vapors from multiple sources, or maintaining a separation between multiple vapors introduced into the showerhead.

The exemplary semiconductor processing apparatus 500 may also comprise a gas removal system constructed and arranged to remove gases from the reaction chamber 502. For example, the removal system may comprise an exhaust port 522 disposed within a wall of the reaction chamber 502, an exhaust line 524 in fluid communication with the exhaust port 522, and a vacuum pump 526 in fluid communication with the exhaust line 524 and configured for evacuating gases from within the reaction chamber 502. Once the gases have been exhausted from the reaction chamber 502 utilizing the vacuum pump 526, the gases may be conveyed along additional exhaust line 528 and exit the apparatus 500.

The exemplary semiconductor processing apparatus 500 may further comprising a controller 530 operably connected to the precursor delivery system 504, the reaction chamber 502, and the removal system by means of exemplary control lines 532A, 532B, and 532C. The controller 530 may comprise electronic circuitry to selectively operate valves, heaters, flow controllers, manifolds, pumps and other equipment associated with the semiconductor processing apparatus 500. Such circuitry and components operate to introduce precursor gases and purge gases from precursor delivery system 504. The controller 530 may also control the timing of precursor pulse sequences, temperature of the substrate and reaction chamber, and the pressure of the reaction chamber and various other operations necessary to provide proper operation of the semiconductor processing apparatus 500. The controller 530 may also comprise a memory 534 provided with a program to execute semiconductor processes when run on the controller 530. For example, the controller 530 may include modules such as software or hardware components (e.g., FPGA or ASIC) which perform certain semiconductor processes, such as etching processes, cleaning processes, and/or deposition processes, for example. A module can be configured to reside on an addressable storage medium of the controller 530 and may be configured to execute one or semiconductor processes.

In some embodiments of the disclosure, the controller 530 may be connected (either electrically and/or optically) to the array sensors 216 and to other components associated with the semiconductor processing apparatus 500. For example, the array of sensors 216 may provide a control output to the controller 530 and the controller 530 may in turn deliver an associated control output to components associated with the semiconductor processing apparatus 500 to enable a uniform reaction rate within the reaction chamber 502. As a non-limiting example, the reaction chamber 502 may be configured for a deposition process, such as, for example, an atomic layer deposition process and/or a chemical vapor deposition process, and the array of sensors 216 may provide a control output to the controller 530 which in turn delivers an associated control output to the components associated with the semiconductor processing apparatus 500 to enable a uniform deposition rate of material within the reaction chamber 502.

In some embodiments of the disclosure, the array of sensors 216 provide a control output to the controller 530 dependent on the fill level 211 of the liquid chemical 206 disposed within the vessel 202. For example, the control output from the array of sensors 216 may vary depending on the fill level 211 of the liquid chemical 206 disposed within the inner volume 204 of the vessel 202. The fill level dependent control output from the array of sensors 216 may be utilized by the controller 530 to adjust one or more control parameters that may affect the deposition rate of a material within the reaction chamber 500. As a non-limiting example, the controller 530 may adjust one or more of the liquid chemical temperature, the substrate temperature, the flow rate of the carrier gas, the flow rate of the vapor phase reactant, or the pulse period of the vapor phase reactant.

In a particular embodiment of the disclosure, the array of sensors 216 may provide a fill level dependent control output to the controller 530 and the controller 530 may in turn deliver an associated control output to the one or more heaters 516 associated with the semiconductor processing apparatus 500. The associated control output from the controller 530 may be utilized to regulate the temperature of the liquid chemical 206 and enable a uniform deposition rate of material with the reaction chamber 502. As a non-limiting example, as the liquid chemical is consumed and the fill level 211 decreases, the array of sensors 216 may provide a fill level dependent control output to the controller 530 indicating the fill level is decreasing. The controller 530 may deliver an associated control output to the one or more heaters 516 which instructs the one or more heaters 516 to increase the temperature of the liquid chemical 206 thereby increasing the vapor pressure of the liquid chemical 206 and counteracting any decrease in vapor phase reactant flow out from the vessel 202 to the reaction chamber 502. Therefore, in some embodiments, the array of sensors 216 may provide a fill level dependent control output to the controller 530, and the controller 530 in turn may provide an associated control output to components associated with the semiconductor processing apparatus 500 to deliver a uniform dose of vapor phase precursor from the precursor delivery system 504 to the reaction chamber 502.

The embodiments of the disclosure may also include methods for dispensing a vapor phase reactant to a reaction chamber. In some embodiments the method may comprise: flowing a carrier gas into an inlet of a vessel having an inner volume configured to contain a liquid chemical; sensing a fill level of the liquid chemical by providing an array of sensors configured for detecting a fill level of the liquid chemical disposed within the inner volume; wherein the array of sensor are vertically distributed with the inner volume with an irregular vertical interval between adjacent sensors; and flowing a vapor phase reactant from an outlet of the vessel to a reaction chamber.

In some embodiments, the array of sensors may comprise a linear array of sensors. In some embodiments, the vertical interval between adjacent sensors may increase form an upper-most sensor to a lower-most sensors and in particular embodiments, the concentration of sensors may be greater in an upper portion of the inner volume compared with the concentration of sensors in a lower portion of the inner volume. In some embodiments, the array of sensors may comprise an array of digital sensors that either detects the presence or absence of a liquid at the sensor location and in particular embodiments the digital sensors may comprise digital ultrasonic detectors.

In some embodiments, the method of sensing a fill level of the liquid chemical may further comprise providing an additional array of sensors configured for detecting the fill level of the liquid chemical, wherein the additional array of sensors are vertically distributed within the inner volume with an irregular interval between adjacent sensors. In some embodiments, the additional array of sensors may comprise a linear array of sensors and the vertical interval between the adjacent sensors may increase from an upper-most sensor to a lower-most sensors. In some embodiments, the additional array of sensors may comprise an array of digital sensors that either detects the presence or absence of a liquid at the sensor location and in particular embodiments the addition array of sensors may comprise an array of digital ultrasonic sensors. In some embodiments, the methods of sensing the fill level of a liquid chemical disposed within the inner volume may comprise providing an array of sensors and an additional array of sensors, wherein each sensor of the array and the additional array may be disposed at a different vertical position within the inner volume of the vessel.

The methods of the disclosure may also comprise creating a control output from the array of sensors and providing the control output to a controller associated with a semiconductor deposition apparatus. The methods of the disclosure may further comprise creating an associated control output from the controller which may be delivered to the semiconductor deposition apparatus to enable a uniform deposition rate of a material. In some embodiments, the associated control output from the controller is delivered to one or more heaters associated with the semiconductor deposition apparatus and configured for heating the liquid chemical to thereby regulate the temperature of the liquid chemical and enable the uniform deposition rate of the material.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for dispensing a vapor phase reactant to a reaction chamber, the method comprising:
flowing a carrier gas into an inlet of a vessel having an inner volume configured to contain a liquid chemical;
sensing a fill level of the liquid chemical by providing an array of sensors configured for detecting a fill level of the liquid chemical disposed within the inner volume, wherein the array of sensors are vertically distributed within the inner volume with an irregular vertical interval between adjacent sensors; and
flowing a vapor phase reactant from an outlet of the vessel to a reaction chamber.

2. The method of claim 1, wherein the array of sensors comprises a linear array of a plurality of sensors.

3. The method of claim 1, wherein the vertical interval between adjacent sensors increases from an upper-most sensor to a lower-most sensor.

4. The method of claim 1, wherein the concentration of sensors is greater in an upper portion of the inner volume compared with the concentration of sensors in a lower portion of the inner volume.

5. The method of claim 1, wherein the array of sensors comprises an array of digital ultrasonic sensors.

6. The method of claim 1, wherein sensing a fill level of the liquid chemical further comprises providing an additional array of sensors configured for detecting the fill level of the liquid chemical, wherein the additional array of sensors are vertically distributed within the inner volume with an irregular interval between adjacent sensors.

7. The method of claim 6, wherein the additional array of sensor comprises a linear array of sensors comprising a plurality of sensors and the vertical interval between the adjacent sensors increases from an upper-most sensor to a lower-most sensor.

8. The method of claim 6, wherein the additional array of sensors comprises an array of digital ultrasonic sensors.

9. The method of claim 6, wherein each sensor of the array and the additional array are disposed at a different vertical position within the inner volume.

10. The method of claim 1, further comprising creating a control output from the array of sensors and providing the control output to a controller associated with a semiconductor deposition apparatus.

11. The method of claim 10, further comprising creating an associated control output from the controller which is delivered to the semiconductor deposition apparatus to enable a uniform deposition rate of a material.

12. The method of claim 11, wherein the associated control output from the controller is delivered to one or more heaters associated with the semiconductor deposition apparatus and configured for heating the liquid chemical to thereby regulate the temperature of the liquid chemical and enable the uniform deposition rate of the material.
